(19) United States
(12) Patent Application Publication
(10) Pub. No.: US 2009/0283766 A1
(43) Pub. Date: Nov. 19, 2009

(54) Methods for increasing film thickness during the deposition of silicon films using liquid silane materials

(75) Inventor: Eric Sirkin, Palo Alto, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silexos, Inc., Palo Alto, CA (US)

(21) Appl. No.: 12/454,186

(22) Filed: May 12, 2009

Related U.S. Application Data
(60) Provisional application No. 61/054,336, filed on May 19, 2008.

(51) Int. Cl. H01L 29/04; H01L 21/20

(52) U.S. Cl. 257/52; 438/482; 438/486; 257/75; 257/E21.133; 257/E29.003

(57) ABSTRACT

Embodiments in accordance with the present invention relate to the fabrication of thin (>1 μm) polycrystalline, nanocrystalline, or amorphous silicon films on a substrate. Particular embodiments utilize liquid sources of silane, including but not limited to cyclohexasilane (CHS), cyclopentasilane (CPS) or related derivatives of these compounds. In one embodiment, the silane is applied in liquid form contained by the use of a series of raised walls. Subsequent polymerization results in the material being a solid form. In other embodiments, the silane is applied as a liquid which is then frozen, with subsequent localized melting allowing polymerization to convert the material into a stable solid form. Embodiments of the present invention are particularly suited for forming thick (>10 μm) silicon films needed to achieve light absorption efficiencies deemed acceptable for thin film photovoltaic devices.

### CROSS-REFERENCE TO RELATED APPLICATION

The instant nonprovisional patent application claims priority to U.S. Provisional Patent Application No. 61/054,336 filed May 19, 2008 and which is incorporated by reference in its entirety herein for all purposes.

### BACKGROUND

Traditional methods for depositing silicon based films, either amorphous, polycrystalline, or crystalline, have relied on using techniques such as Chemical Vapor Deposition CVD, Plasma Enhanced Chemical Vapor Deposition PECVD or Atmospheric Pressure Chemical Vapor Deposition APCVD. A common technique applied in the Integrated Circuit Industry is Low Pressure CVD (LPCVD).

In LPCVD, depending on the particular process, one or more silicon wafers are placed into a vacuum chamber. Gases are evacuated and an inert atmosphere of gas is introduced into the flow while the substrates are heated, often to temperatures of more than 600° C. Silane gas is introduced into the chamber, often in the presence of N₂ as an inert ambient at a total pressure of about 100 Pa (˜0.001 atmospheres).

After the desired film thickness is achieved, the chamber is evacuated, purged with N₂, and cooled to room temperature and the chamber opened so the substrates can be removed. Using this method, deposition rates of no more than 0.01 μm/minute can be achieved. For the integrated circuit industry, polycrystalline silicon films thicknesses of 0.3 μm are used, and the conventional CVD methods are adequate, as film deposition can be completed within 30 minutes. Taking into account the temperature ramping, evacuation, flushing, etc. the total cycle time of a deposition can take 3-4 hours. This makes processing of a single substrate at a time impractical.

In order to increase the throughput of CVD approaches, an improved technique known as plasma-enhanced chemical vapor deposition (PECVD) was developed, so that single wafers could be processed. While not typically used for polycrystalline (p-Si) silicon films, this technique is commonly used for the deposition of silicon dioxide films in the integrated circuit industry. This PECVD technique is also used in the deposition of amorphous silicon (a-Si) films for the Amorphous Silicon Thin Film Transistor arrays used in flat panel displays. Again, however, deposition rates are only of the order of 0.01 μm/minute for silicon films.

Solar cells convert photons from the sun into electrons based on the photoelectric effect. Among the various materials being used for PhotoVoltaic (PV) solar cells, crystalline silicon cells are the most suitable since (1) silicon is abundantly available (2) crystalline silicon has a bandgap of 1.1 eV and this is close to being optimal for AM1.5 solar spectrum and (3) silicon processing has been used for a long period of time in the semiconductor industry and cells with highest production efficiencies have been demonstrated with silicon.

In contrast with the integrated circuit industry, the solar energy industry utilizes A-Si and P—Si films having thicknesses substantially greater than 1 μm, with film thicknesses of >10 μm or even >25 μm needed. Typically A-Si film thicknesses are <0.5 μm, and P—Si thicknesses are generally greater than 1 μm in order to absorb adequate sunlight. Owing to the processing times required to create such thick films, the use of conventional CVD techniques to deposit films ≧1 μm is prohibitively expensive for Thin Film Photovoltaic Solar Cells.

Accordingly, there is a need in the art for techniques for forming thick layers of amorphous and polycrystalline silicon in commercially practicable times, for use in the manufacture of photovoltaic cells.

### BRIEF SUMMARY

Embodiments in accordance with the present invention relate to the fabrication of thin (>1 μm) polycrystalline, nanocrystalline, or amorphous silicon films on a substrate. Particular embodiments utilize liquid sources of silane, including but not limited to cyclohexasilane (CHS), cyclopentasilane (CPS), or related derivatives of these compounds. In one embodiment, the silane is applied in liquid form contained by the use of a series of raised walls. Subsequent polymerization results in the material being a solid form. Another embodiment employs a depression etched or otherwise created on the substrate resulting in a self contained reservoir for the liquid. In other embodiments, the silane is applied as a liquid which is then frozen, with subsequent localized melting allowing polymerization to convert the material into a stable solid form. Embodiments of the present invention are particularly suited for forming thick (>10 μm) silicon films needed to achieve light absorption efficiencies deemed acceptable for Thin Film Photovoltaic Devices.

An object of certain embodiments of the present invention is to provide a method for applying a liquid film of a cyclosilane material to a flat substrate with the goal of achieving a thick film (>0.1 μm) of amorphous, nanocrystalline, polycrystalline or crystalline silicon.

Another object of embodiments of the present invention is to be able to apply the film while maintaining uniformity across the substrate, of physical film properties such as thickness, and electrical and optical film properties.

Still another object of embodiments of the present invention is to allow the inexpensive application of such Si films in a production-based environment.

Yet another object of embodiments in accordance with the present invention is to apply the films while minimizing contamination of the resulting film from either the ambient atmosphere or materials/equipment that the liquid material may come into contact with during its handling.

Another object of embodiments of the present invention is to provide a technique that is amenable to inline processing of large area substrates, making pre- and post-processing of the applied film relatively simple and low cost through the use of existing technologies.

Another object of embodiments in accordance with the present invention is to allow the use of “self-aligned” structures in the application of the thin films to the substrates. Such self-aligned structures minimize subsequent processing costs and throughput, and maximize the yield of the manufacturing process.

Another object of certain embodiments in accordance with the present invention is to apply the cyclosilane and/or polysilane material in liquid form at a temperature above its melting point to a substrate that is held at a temperature below the melting point. When the liquid comes into contact with the substrate it freezes and thereby permits a thicker film to be applied independent of the viscosity of the liquid. This also obviates the need for adding a material to the silane precursor intended to solely promote the adhesion of the liquid to the substrate.

### BRIEF DESCRIPTION OF THE FIGURES

FIG. 1 is a simplified flow diagram illustrating the steps of a process of forming a silicon layer according to an embodiment of the present invention.

FIGS. 1A-1N are simplified cross-sectional views of steps of an embodiment of forming a silicon layer according to the present invention.

FIGS. 2-5 are simplified plan views of various patterns of barriers formed on a substrate according to embodiments of the present invention.

FIG. 6 is a simplified schematic view of the succession of processing chambers employed in the formation of a silicon layer according to one embodiment of the present invention.

FIG. 7 is a simplified schematic view of the succession of processing chambers employed in the formation of a silicon layer according to an alternative embodiment of the present invention.

FIGS. 8A-8D are simplified cross-sectional views of various steps of a process for forming a silicon film according to an alternative embodiment of the present invention.

FIGS. 9A-9CC are simplified views of various steps of a process for forming a silicon film according to an alternative embodiment of the present invention.

FIG. 9D is an example of a design for the fluid retaining ring used in the processing steps illustrated in FIGS. 9A-9CC.

FIGS. 10A-10D are simplified cross-sectional and top level views of various steps of a process for forming a silicon film according to an alternative embodiment of the present invention.

### DETAILED DESCRIPTION

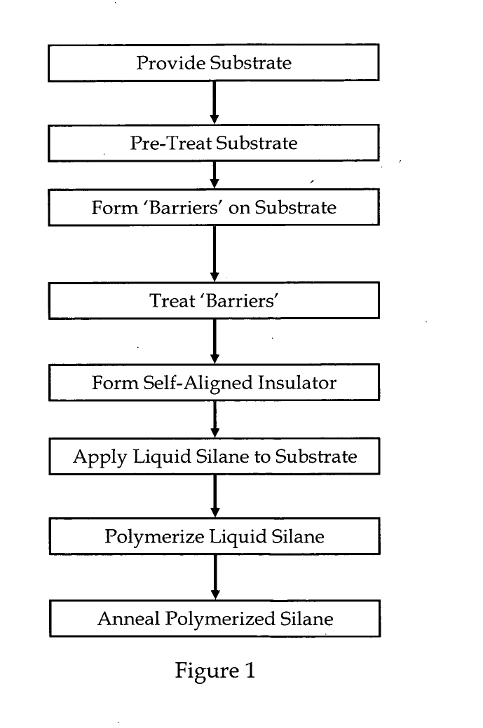

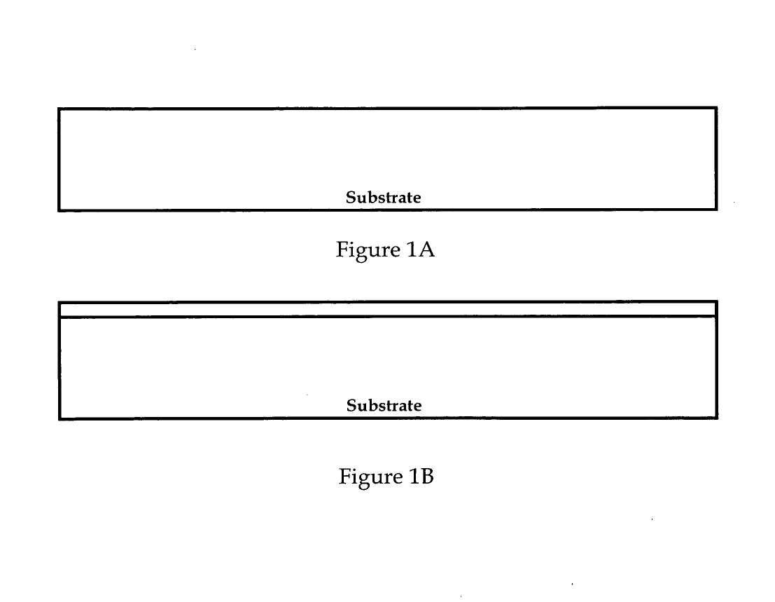

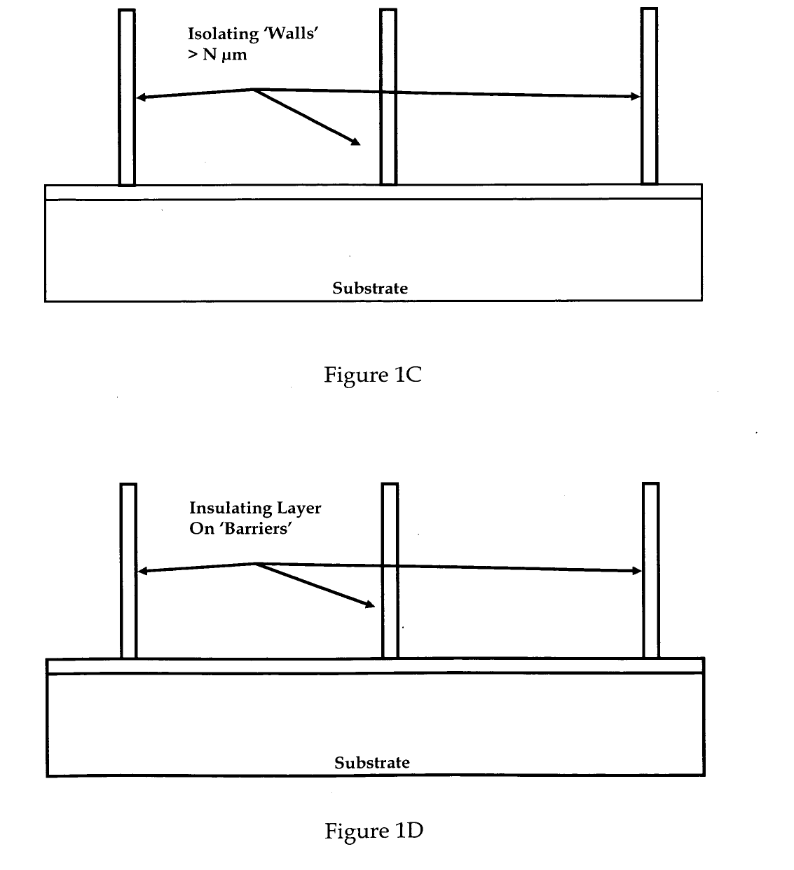

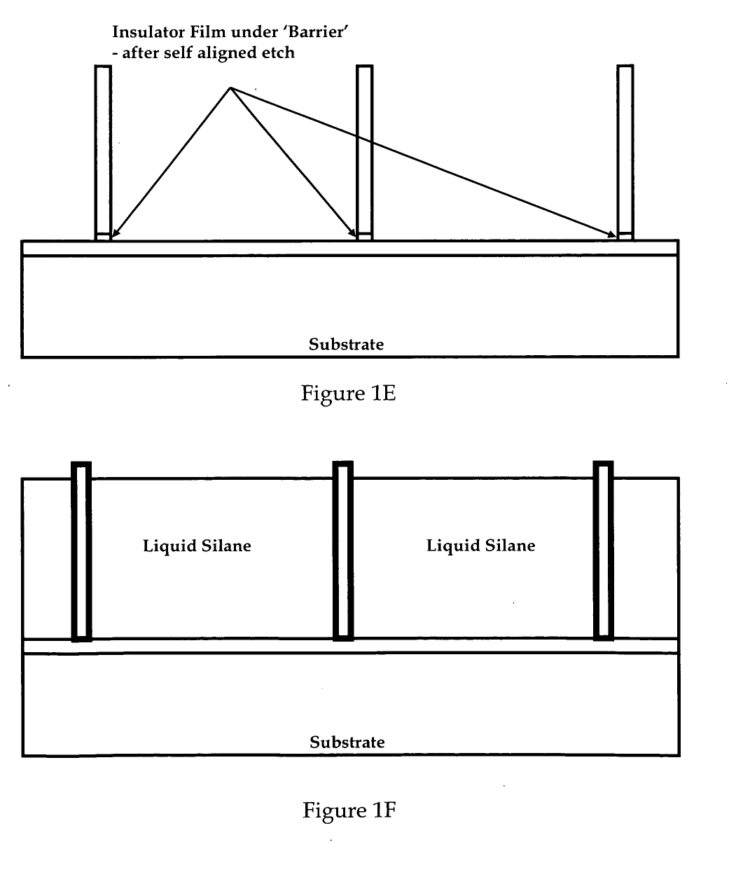

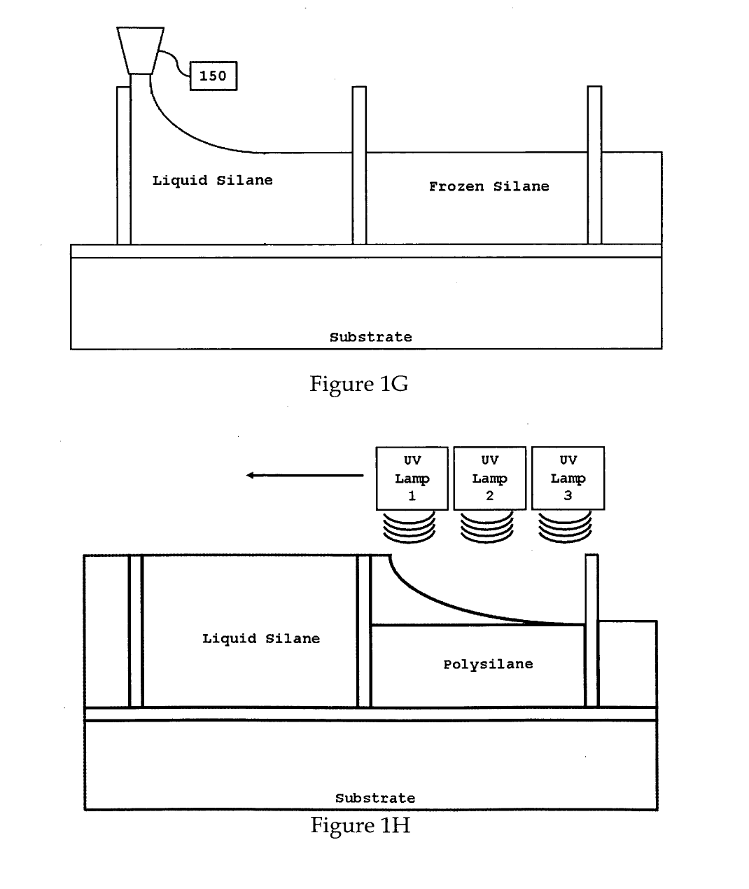

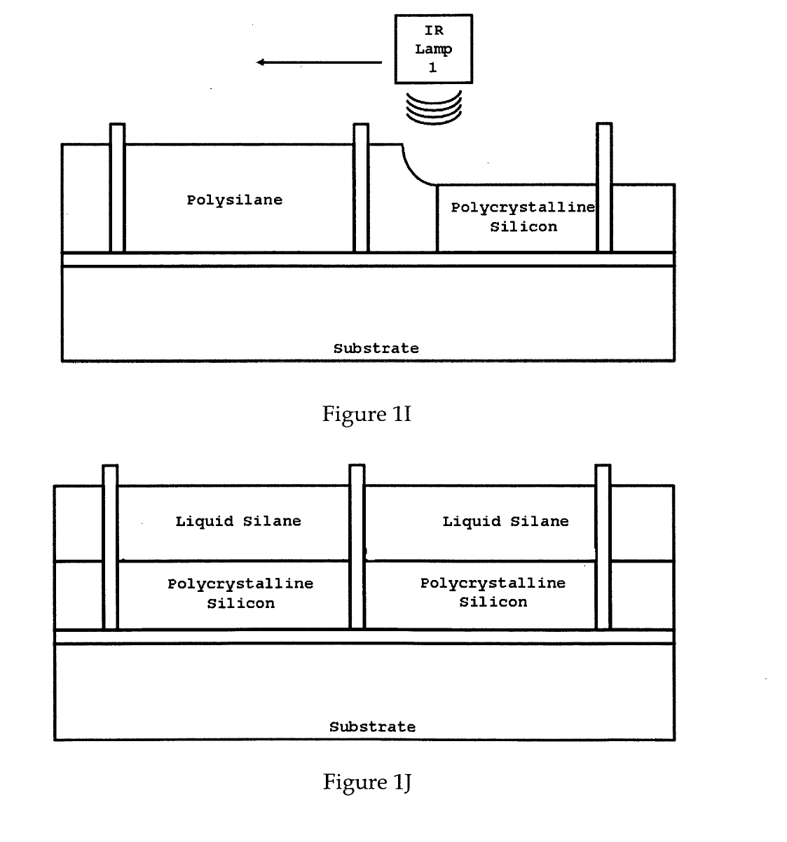

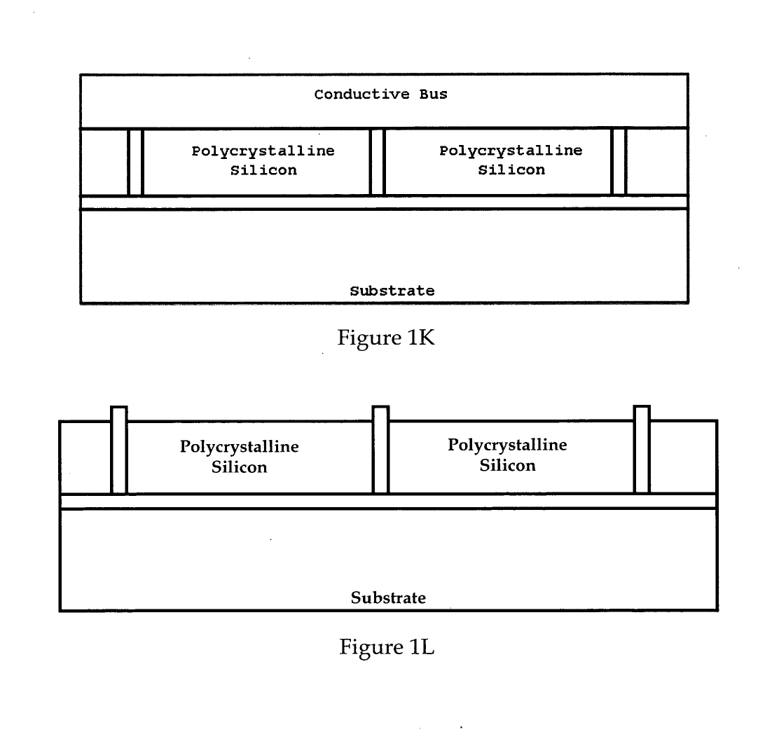

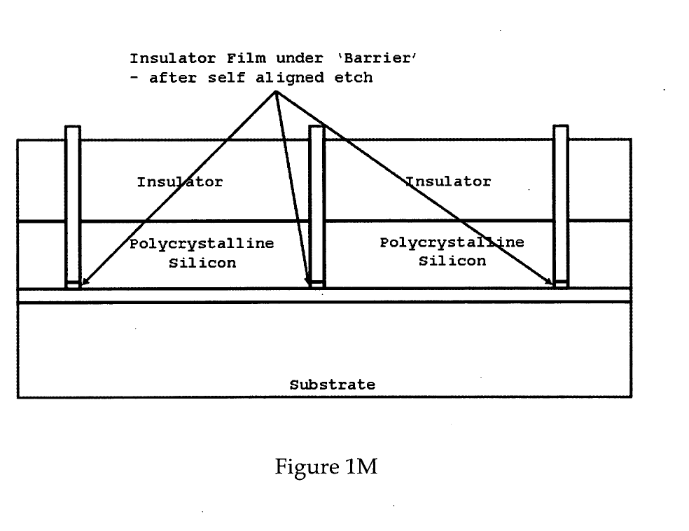

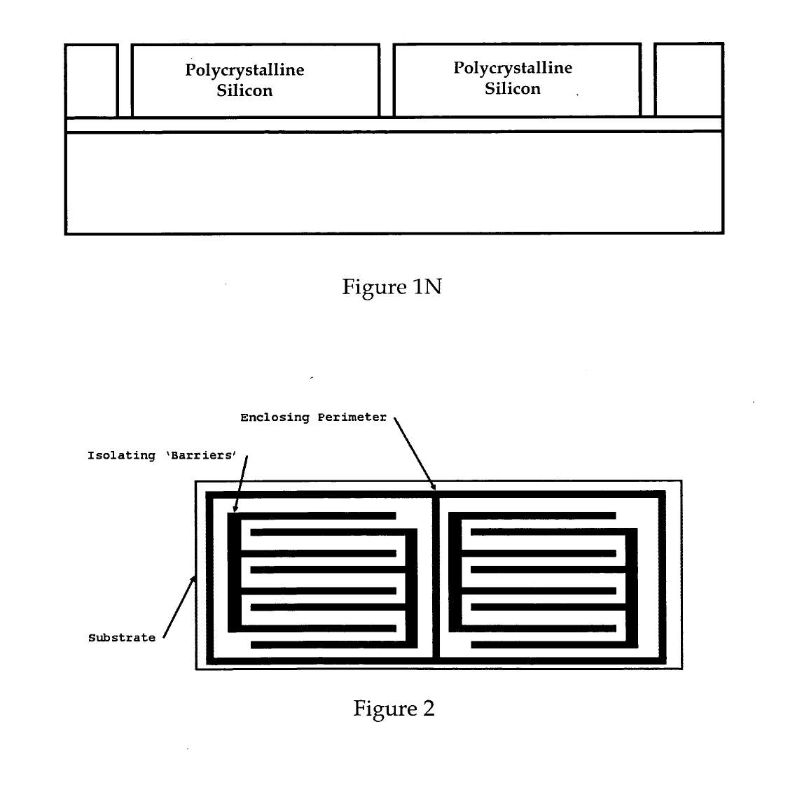

FIG. 1 is a simplified flow diagram showing steps of a process of forming a silicon layer according to an embodiment of the present invention. FIGS. 1A-N are simplified cross-sectional views of processes according to embodiments of the present invention for fabricating a silicon film on a substrate.

In FIG. 1A, a substrate having a thickness of >100 μm is provided. Embodiments in accordance with the present invention are not limited to the use of a substrate of any particular thickness, so long as the substrate exhibits sufficient rigidity to support the various materials present during fabrication of the silicon film. The substrate could be in the form of a plate or a sheet, as long as it is flat.

Depending upon the particular application, the substrate material could comprise a ceramic (e.g. glass), a plastic (e.g. polyethylene), a metal (e.g. Aluminum or stainless steel), or a semiconductor (e.g. Silicon, Germanium, or Gallium Arsenide).

In order to enhance the adhesion of the liquid polysilane that is subsequently to be applied, the surface of the substrate can optionally be pre-treated. Examples of such pre-treatments include but are not limited to exposure of the substrate to UV radiation in either an oxidizing or reducing ambient environment, or the application and removal of a ‘primer’ material or other film pre-treatments commonly used in the industry.

The pre-treatment is an optional step that is not required. However, pre-treatment may be desirable for fabricating certain types of devices. FIG. 1B shows that one example of such a pre-treatment includes the formation of an intermediate adhesion layer if the liquid polysilane layer does not adhere or wet well with the substrate material.

Another possible type of pre-treatment is the formation of a conducting layer. Specifically, where the underlying substrate is a non electrically conducting material (e.g. ceramic, plastic, or semiconductor), a conducting layer over the substrate may be needed. Where the film is being incorporated as part of a solar cell and the substrate is transparent to incident light, the conducting layer may be also be made from an optically transparent material such as Indium Tin Oxide or Zinc Oxide.

Still another possible type of pre-treatment is the formation of an insulating layer. For example, if the substrate is formed from a conductor (e.g. Aluminum), then it may be necessary to form an electrically insulating layer on top of the substrate prior to applying the liquid polysilane.

FIG. 1C shows a second step in the process, wherein barriers are formed on the substrate. The function of the walls or barriers is the same in principle as the walls of a reservoir to retain water. Either through the use of natural physical boundaries, such as mountains surrounding a valley, or man made barriers, it is possible to store and retain water (a fluid) at depths that would ordinarily not be possible. Water enters the “reservoir” either by streams that feed it and/or by direct rainfall.

Here, in an analogous fashion the barriers are created to retain the liquid silane fluid (e.g. CPS or CHS) that has been applied to the substrate. As in the case of a reservoir the height of these barriers must exceed the expected depth of the fluid.

The particular embodiment of FIG. 1C illustrates barriers exhibiting large aspect ratios. However, this is not required by the present invention, and the physical parameters of the barriers (e.g. aspect ratio, pitch, shape) may vary, so long as the barriers serve the function of containing the liquid polysilane. While not necessary for the implementation of this invention, in certain embodiments it may be desirable to space apart the barriers by a distance of approximately 2× their height.

The barriers can be fabricated using any one of several different possible techniques. One technique for fabricating the barriers utilizes an ink jet approach. Specifically, the material of the barriers could be dispensed through an ink jet printer as a fluid, which later solidifies on contact with the substrate due to the rapid evaporation of the solvent in which the ink is dispersed.

Another possible technique for fabricating the barriers utilizes screen printing. In such an approach, the material of the barriers can be dispensed by application of the ink across a screen mask that comes into close contact with the flat substrate.

Still another possible technique for fabricating the barriers utilizes deposition, masking, and etching. In such an approach, a film is deposited on the substrate either through evaporation in a vacuum, sputtering in a vacuum, immersion, blanket coating, or some other mechanism which can coat the entire substrate to a uniform thickness. A resist material (such as positive or negative photoresist) is then deposited onto the film, which is subsequently exposed either using a scanning device like a laser, a screen mask with light behind it, a photomask, or some other means for projecting an image onto the photosensitive material. The photoresist layer is then exposed to a ‘developer’ which removes either the exposed (positive photoresist) or unexposed (negative photoresist) parts of the photosensitive material. The substrate is then exposed to an etching agent such as an acid which dissolves the exposed areas of the thin film, leaving the barriers. The residual photoresist is then removed using a different acid.

Yet another possible technique for fabricating the barriers utilizes an electro-deposition approach (e.g. electroplating). If the substrate is a conductor and an electrically insulating film is present over the substrate, then using one of the techniques described above an appropriate pattern is deposited on top of the insulating film. An acid is used to etch through the insulator to form the desired pattern of the barriers. A conducting film can then be formed by immersing the substrate with the films into a bath containing the proper dissolved salt of the metal to be deposited. When the appropriate voltage and current are applied to the substrate, the desired metal will deposit selectively on those regions exposed through the insulating layer. If the substrate is conductive two films would be needed: first a conductive layer, and then an insulating layer over the conductive layer.

Yet another possible technique for creating a barrier to retain the liquid utilizes a mechanical ring that is applied by pressure to the surface of the substrate. The ring follows the perimeter of the substrate, and thereby creates a natural retaining wall to contain the fluid to a determined thickness.

Depending upon the particular application, various types of materials can be used to form the barrier structures. For example, the barriers can be formed from a conductive metal.

Specifically, the barriers can be formed from metal if the barriers are fabricated by electroplating as described above. Metal barriers could also be used if it is desired to use the barriers not just to create physical reservoirs for liquid silane, but also to establish electrical contact to an underlying layer. Apart from its conductive properties, the use of metal may also be desirable because it is relatively easy to deposit and remove.

Alternatively, the barriers can be formed from polymeric materials. Polymeric materials such as Polymethylmethacrylate (PMMA) are commonly used in the electronics industry, as they are inexpensive and easy to apply and remove. Polymer materials such as these could also be used in the formation of the barrier structures.

Where a polymer is used to form the barrier structures, then most likely the barriers will need to be removed once the liquid silane has been converted into a solid. This is because the polymer materials frequently are unstable at the high temperatures of subsequent treatments converting the polysilane film into an amorphous or polycrystalline silicon film.

Still further alternatively, the barriers can be formed from a ceramic material such as glass. The use of a ceramic material for the barrier structures would allow higher temperature processing than with barriers formed from a polymeric material; however ceramics are typically not as easy to apply as a polymer.

If left in place, the ceramic barriers would also act as an electrical isolation between the active areas defined by the barriers. Alternatively, a ceramic barrier structure could be removed through an etching process, and possibly later replaced with a conductor or semiconductor layer.

Whatever the material that is used to form the barrier structures, once the barriers have been defined it may be advantageous to treat the surfaces of the barriers. This is shown in FIG. 1D. Such treatment may promote the adhesion of the silane material, and/or may encourage growth of specific grain sizes during the annealing taking place later in the processing flow.

One example of such a treatment for the barrier structures involves irradiation with ultraviolet (UV) radiation. Specifically, exposing the surface of the barriers to a UV lamp in the presence of air, O₂, or another oxidizing environment, results in a small amount of ozone (O₃) production. Exposure to ozone can break bonds at the surface of the barriers and promote adhesion of subsequently deposited films such silane.

Another example of treatment for the barriers involves exposure to an acid. Specifically, depending on the particular barrier material, exposing the surface to a dilute acid can also result in the oxidation of the film surface and thereby promote adhesion and wetting of the surface to the silane.

Still another example of treatment for the barriers involves anodization. Specifically, anodization of metal films such as aluminum and tantalum oxides the metal film at its surface. Anodization can be induced through the treatment of the material by an acid, with or without passing an electric current through the material. Oxide thicknesses of as little as 0.1 to 0.3 μm, exhibiting favorable insulating properties can be readily achieved utilizing such techniques. In particular embodiments, thicknesses of Al₂O₃ films have been achieved by anodizing aluminum in H₂SO₄.

In fact, using aluminum as the material for the barriers may confer a number of advantages. For example, aluminum forms a stable eutectic with silicon, thereby producing a low resistance (excl. Shottky barrier effects) contact.

Moreover, various techniques for the anodization of aluminum are known. Specifically, creating a surface texture that generates the right size nucleation sites for the polycrystalline silicon during the annealing process, should be possible and relatively easy to control. Such an approach would allow different texturing for the barriers versus the surface of the underlying substrate. This is advantageous, insofar as the texture of the underlying substrate may be created for a different purpose (e.g. to enhance internal reflection and the ability of the substrate to transmit light).

It is also possible to thoroughly anodize the aluminum film, resulting in a durable, process-resistant, and temperature-resistant barrier material that is completely insulating. Finally, it may be possible to partially anodize aluminum so that it is electrically insulated from the polycrystalline silicon formed from the liquid silane, yet is electrically conductive so electrical contact to an underlying film layer can be established.

According to particular embodiments of the present invention, the barriers may need to be electrically conductive, and also electrically isolated from the silicon film that is ultimately formed from the liquid silane. In certain such embodiments, it may be desirable to use the barrier structures to form a self-aligned electrical contact to an underlying conductive film, yet have the barriers insulated from the silicon layer that is to be formed from the liquid silane. This is shown in FIG. 1E. Such a configuration could be a requirement of a thin film photovoltaic cell, where the underlying conductive film is either a transparent metal conductor, or a multilayer transparent metal conductor & emitter layer such as n-silicon.

At least three approaches are possible to achieve this configuration. In a first approach, the film is oxidized by applying heat in an oxidizing ambient environment. In a second possible approach, the metal film is anodized using a combination of acid, electric current and/or heat.

In a third possible approach, an insulating film may be deposited either selectively on the conductor or, deposited on all of the exposed surfaces, including the underlying film. Application of an anisotropic etch would remove the insulating material only from surfaces parallel to the substrate surface.

In accordance with particular embodiments, a film intervening between a barrier and a substrate is electrically conductive, and it is desirable to prevent a barrier made from a conducting material, from being in electrical contact with the film. In such an application, an insulating layer may be formed on top of the film before the material of the barrier is deposited. Methods for forming the insulating layer include depositing an insulating film, or oxidizing the surface of the film by treating its surface with some combination of heat, oxidizing environment, and possibly an electric current.

The barriers may be formed using one of the methods described above. However, for this application the oxide is also etched, as it is a self-aligned mask by the barriers. This yields the structure shown in FIG. 1E, with the barrier electrically isolated from the polycrystalline silicon. Because the insulating layer is self aligned with the barrier, it requires no special masking step.

In the embodiment of FIG. 1E, the barrier is electrically conductive and self aligns with the insulating layer below it, barrier etch removal. This obviates the need for any additional masking steps.

As shown in FIG. 1F, once the barriers have been formed and then treated (if appropriate), in the next step the liquid silane is applied. Some silane materials for use with embodiments of the present invention may be liquid at room temperature, for example cyclopentasilane (CPS), cyclohexasilane (CHS), and certain derivatives of those compounds. By allowing application in the liquid phase, such liquid silane materials offer definite advantages, and in particular avoid the need for expensive and complex vacuum deposition equipment.

Any number of possible techniques can be employed to deposit the liquid silane films. For example, in an immersion approach the flat substrate with the barriers formed thereon, is immersed in a bath of the liquid silane with the barrier structures facing upward. The liquid overflows the barriers and fills crevices created by the barriers to at or near the height of the barriers. The substrate is then carefully removed from the bath so that the substrate remains parallel with the Earth's surface, and gravity maintains the liquid silane contained on the surface of the substrate.

Alternatively, the liquid silane can be deposited by roller coating. In this approach, the liquid silane is applied to the substrate by a roller with a steady stream of material supplied as it rolls around its axis. The roller then is either brought into physical contact with the substrate, or into near contact with the substrate separated by a thin screen. A translation stage moves the roller across the width of the substrate, depositing the liquid silane as it rolls.

Further alternatively, the liquid silane can be deposited by curtain coating. In this approach, a dispenser having a head at least as wide as the width of the substrate, traverses the length of the substrate dispensing the fluid evenly along the entire width of the substrate.

Further alternatively, the liquid silane can be deposited by a rotogravure printing apparatus. In this approach, a drum whose surface has micro-cavities etched into its surfaces, rotates through the liquid silane drawing the fluid into the cavities. When the surface of the drum comes into contact with the substrate that is to be coated, the liquid transfers from the drum surface to the substrate in a pattern replicating the structure of the micro-cavities in the drum surface.

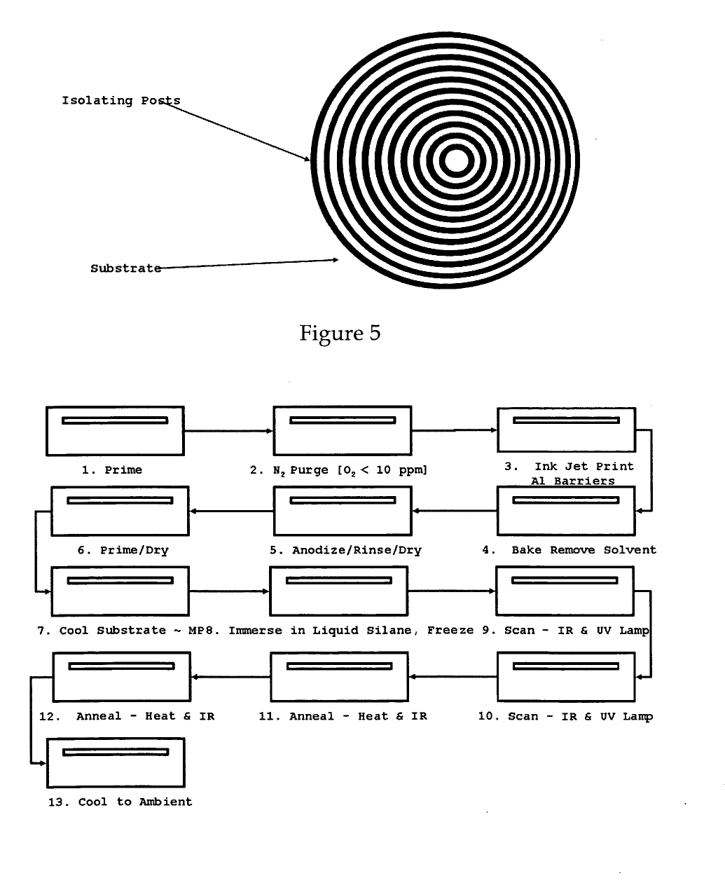

The liquid silane could also be applied by spin coating. In such an approach, the substrate is placed horizontally on a chuck that is rotated at high (e.g. >1,000) rpm. The liquid silane is dispensed at the center of the substrate, with the rotation of the substrate serving to spread out the material evenly. Such a spin coating approach may be practicable only where the substrate is circular as well. In such cases, as shown in FIG. 5, the patterns for the barrier structures would be circular.

Whatever technique is employed, uniformity in the thickness of the liquid silane would be highly dependent on the uniformity of the height of the barrier structures, as the level of the liquid will tend to rise to that height. Thus, embodiments of the present invention may offer an advantage in that application of the liquid silane need not be performed in a way that confers a high degree of uniformity. The method only need to dispense the fluid so that cavities between the barriers are filled to the height of the barriers, and any excess liquid spills over the edge of the substrate where it can be received (and possibly re-used). This removal of the strict requirements of application of a film of uniform thickness may thus avoid one important (and hard to achieve) dependency.

While the above embodiment has illustrated the application of liquid silane that is maintained as a liquid, this is not required by the present invention. In accordance with alternative embodiments, following application, the liquid silane could be converted to solid form, for example by freezing. Such an approach is shown in the simplified cross-sectional view of FIG. 1G, wherein liquid silane is applied by a box coating dispenser head 150. Additional detailed discussion of the conversion of applied liquid silane to the solid state is provided below.

In a next step, as shown in FIG. 1H the applied liquid silane material is polymerized. Such polymerization can be accomplished through the application of heat and/or UV radiation. As heat runs the risk of evaporating some or all of the monomeric cyclosilane before it polymerizes, it is expected that for most applications a combination of heat and UV radiation will result in polymerization of the film.

In one embodiment, the temperature of the substrate and of the deposited liquid silane is maintained above the melting point but well below the boiling point, thereby preventing excessive evaporation of the silane. A UV lamp forms a light beam that runs along the width of the substrate, and the liquid silane is exposed thereto. The UV light causes polymerization of the liquid monomer into a solid polymeric material. Multiple lamps can be mounted and used to expose the liquid silane, as a single exposure may not be sufficient to fully polymerize the material.

The specific form or geometry of the UV lamp is not critical. However, a linear lamp may be conducive to an inline processing manufacturing line. It is also not critical whether the lamps that are scanned relative to the substrate, vice-versa, or both the substrate and the lamps are moved. In addition, it may be necessary to scan multiple times in order to fully polymerize the liquid.

In a next step of the process, as shown in FIG. 1I, the silane material is annealed. According to one embodiment, a temperature of the substrate is increased to drive off much of the H₂ and residual silanes. This annealing will produce a high quality silicon film, maximizing carrier lifetimes and minimizing impurities and creating a stable film.

The specific type of silicon film that is formed (e.g. amorphous, nanocrystalline, or polycrystalline) depends on the particular conditions of the annealing. Specifically, the anneal temperature, ambient atmosphere, and presence of nucleation sites on the substrate surface can influence the type of silicon film that is formed.

FIG. 1I shows use an Infrared Arc Lamp beam running the length of the substrate width in order to anneal the Polysilane. The intensity of the IR lamp, its focal point at the substrate surface, its scan rate, the spectral absorption of the film and the initial temperature of the substrate collectively control the local temperature of the annealed film.

At this anneal stage, the film is now a solid. Thus, the temperature can be elevated without concern about evaporation of the liquid silane. At lower (<400° C.) localized anneal temperatures, the film will grow as amorphous silicon. At higher (>650° C.) anneal temperatures, the film will form as polycrystalline silicon. In-between, various phases of nano and micro crystalline silicon will be present.

In particular embodiments where the silicon is to be employed in a solar cell, polycrystalline silicon having grain sizes of >10 μm may be needed to maintain good carrier lifetimes and hence energy conversion efficiencies.

The grain size of the polycrystalline silicon may be influenced by the nature of the underlying surface. For example, surface treatment of barrier structure (for example by anodization of Al under certain known conditions) is conducive to creating the desired size nucleation sites and hence good film quality. Alternatively, acid treatment of a surface can sometimes result in favorable nucleation sites.

The thickness of the film will shrink as density increases with the conversion of polysilane to polycrystalline silicon.

In a particular embodiment, the temperature of the entire substrate can be raised at once using a plate heater on which the substrate rests. Alternatively, the substrate can be heated in a single wafer or batch furnace.

Certain process steps may follow the annealing. For example, FIG. 1J shows the application of additional liquid silane over the polycrystalline silicon, to increase the thickness of the deposited layer or apply an n-doped film on top of a p-doped film, or vice-versa. FIG. 1K illustrates use of the barrier structures to make low resistance electrical contact with the underlying film. For solar photovoltaic cells, this underlying film may be the emitter silicon film.

In the embodiment of FIG. 1K, the barriers have an insulating layer that isolates them electrically from the polycrystalline silicon film. Electrical contact is established by etching off the top surface of the barriers and the insulating layer, and depositing an electrically conductive line running perpendicular to the barriers. The thickness of the conductive line would be appropriate for handling the currents needed for the solar photovoltaic cells. Possible deposited electrically conducting materials could include Al, Cu, Ag, Ni, Zn, or alloys of these materials. The bus lines could be defined using inks and ink jet technology. Alternatively the bus lines could be screen printed or masked/etched.

In another possible barrier-annealing step, the barrier structures could be etched back. FIG. 1L illustrates a structure resulting from etching back the barriers to the same height as the polycrystalline silicon film that has been formed. Such removal of barrier material may be useful where excess height of the barriers could cause problems with coverage and contiguity for subsequent film depositions or lithographic steps.

In still another possible barrier-annealing step, an insulator film could be formed. FIG. 1M illustrates another example of the barrier structure in processing the film. In this example the electrically conductive barrier structures are isolated from the underlying film, but form an electrically conductive contact with the polycrystalline silicon film. An insulating layer is applied above the polycrystalline silicon film, to isolate the barriers from other films and structures to be created in subsequent processing, for example other solar junctions used in the formation of a multi-junction solar cell. In this embodiment, electrical contact between the barrier structures and the polycrystalline silicon film is established through the sides of the barriers.

Yet another possible barrier-annealing step is to isolate the polycrystalline silicon structures. For example, there may be particular applications where it is desirable to remove the barriers following their use to contain the silane material. Such removal could be performed utilizing a selective etching process, for example as shown in FIG. 1N.

In summary, FIG. 2 shows a plan view of an example of an arrangement of barrier structures in accordance with an embodiment of the present invention. The most important features is the enclosure of a perimeter. In order to retain and contain the liquid silane, the barriers must be contiguous around the perimeter of the desired active area of the substrate. Otherwise the fluid will spill over the sides and arrive at a thickness consistent with the viscosity of the liquid silane.

Other components of the barrier arrangement are intended to reduce the rate at which the fluid flows across the substrate. While these other components are not required, they may offer the benefit of reducing a level of spillage.

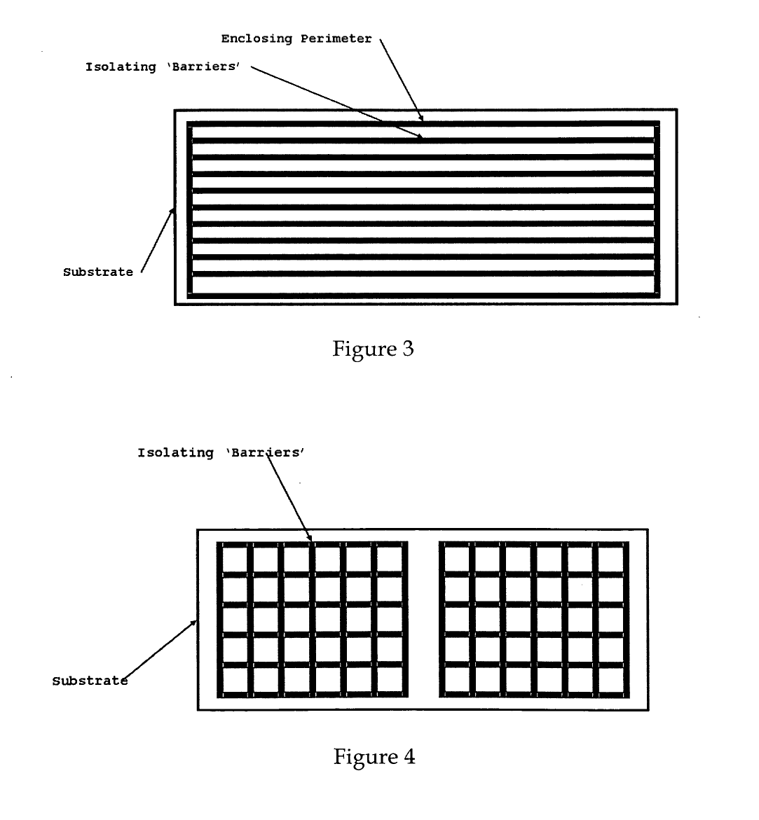

FIG. 3 shows a simplified plan view of another example of an arrangement of barrier structures in accordance with an embodiment of the present invention. In the particular embodiment of FIG. 3, there are a series of contiguously contained cavities for retention of the applied liquid silane. FIG. 4 shows a simplified plan view of yet another example of an arrangement of barrier structures.

FIG. 5 shows a simplified plan view of another barrier configuration, this time with a circular substrate. This embodiment is particularly suited for the application of the liquid silane by spin coating.

While the above embodiments have described processes wherein the silane is maintained as a liquid following its application, this is not required by the present invention. In accordance with alternative embodiments, silane applied in liquid form could subsequently be converted to solid form, for example by freezing.

The following TABLE lists certain physical characteristics of the CPS and CHS materials described in connection with the above embodiments:

TABLE

| Material | Formula | Melting Point | Boiling Point | Density |
|---|---|---|---|---|
| Cyclopentasilane | Si₅H₁₀ | −10.5° C. | 194.3° C. | 0.963 g/ml |
| Cyclohexasilane | Si₆H₁₂ | 16.5° C. | 226° C. | Not Avail. |

The TABLE reveals the CPS and CHS materials to be solids at temperatures near the freezing point of water, yet boil at temperatures substantially higher than water.

Derivatives of the above-referenced liquid cyclosilane materials may also be used to form silicon layers. For example, the CPS or CHS may be modified to include groups containing boron, arsenic, or phosphorous. Such groups could be useful to dope the silicon film so that it exhibit the desired electrically conducting characteristics. During formation of the thin layer, the derivatized liquid cyclosilane could be mixed with the liquid cyclosilane in proportions designed to result in the appropriate doping level, upon the polymerization step taking place.

t room temperature intrinsic crystalline silicon has a concentration of approximately 5×10²² atoms/cc. Doped semiconducting layers of crystalline silicon have concentrations of 10¹³ to 10¹⁸ atoms/cc. In the application described a liquid such as Boro cyclopentasilane [C₅H₉BH₂] would be mixed at a ratio of 1×10⁻⁸:1 to 1×10⁻⁴:1 on a mole basis with raw cyclopentasilane. This solution would then be applied using the same basic technique to achieve a p-doped polycrystalline silicon film.

The physical properties of CPS and CHS indicate that it may be possible to transport the CPS and CHS materials in refrigerated environments as solids, allowing for safer and more economical handling. These properties also indicate that it may be possible to dispense the CPS and CHS materials at temperatures easily achieved in a manufacturing environment, that are just slightly above their melting point.

For example, as previously mentioned in connection with FIG. 1G, in certain embodiments the liquid silane may be dispensed onto a substrate that can then be cooled to a temperature below the melting point. Alternatively, the liquid silane materials may be dispensed onto a substrate that has already been cooled to below the melting point.

In dispensing the materials in this fashion, it is possible to secure the material onto the surface of the substrate as a solid once it has been evenly coated. This greatly helps the handling of the substrate and prevents unnecessary loss of the liquid material. It also reduces the need for intrinsic film adhesion promoters, although the need may not be eliminated.

Prior to being dispensed, the liquid silane is cooled to a temperature a few degrees above its melting point. The substrate is also kept at or slightly above the melting point. As the liquid is dispensed across the width of the substrate, it fills the cavities between the barriers until overflowing the top of the barriers and spills over the sides. Once this has occurred, the temperature of the substrate can be lowered to below the melting point in order to keep the material from spilling any more or moving around the substrate. One possible drawback to this approach is that as thick a film as may be achieved utilizing the alternate approach (see immediately below), may not be possible.

In accordance with an alternative embodiment, the substrate can be maintained at a temperature well below the melting point at the time of dispensing the liquid silane. This induces freezing of the silane as it is dispensed.

An advantage to such an approach is that a film of greater thickness can be achieved. Specifically, because the solidified silane is denser than the liquid silane, it will fill to a lower thickness than in the liquid state. This necessitates a greater amount of silane material to be dispensed for a given end target film thickness.

Possible issues that may be raised by this approach, however, are that the uniformity of the film will be determined by the uniformity of the apparatus dispensing the liquid, and not just the heights of the barrier structures. Also, if the substrate is heated to above the melting temperature, the material in its liquid state will spill over the barriers. Thus, subsequent polymerization of the liquid silane material may need to be either partially or totally complete when the material is in its solid form.

If a foreign material (such as Toluene) is added to the liquid silane when it is dispensed, then this foreign material should be driven off via evaporation before the film can be frozen. In such embodiments the material is thawed before the evaporation can take place.

### EXAMPLES

### Example 1

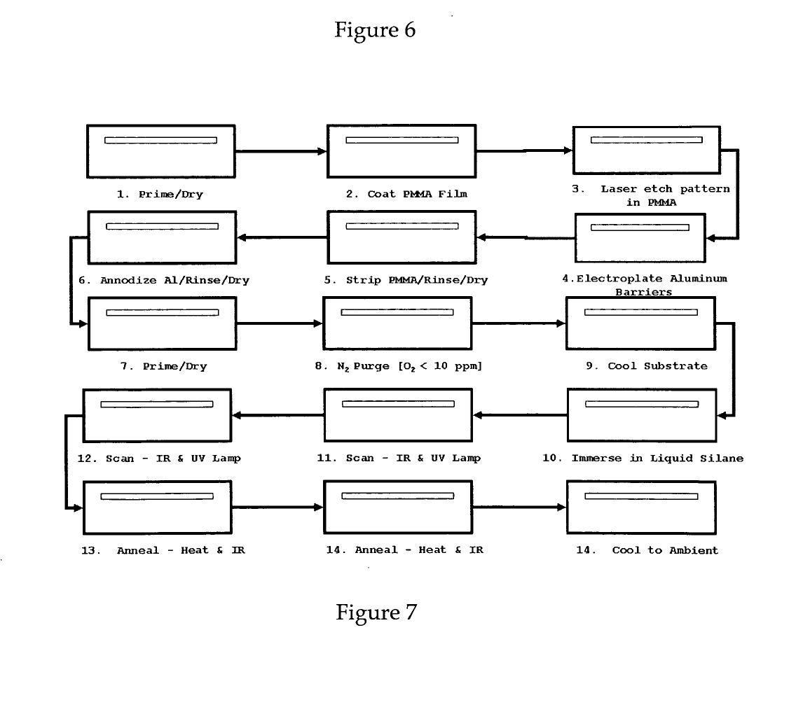

FIG. 6 shows a simplified flow diagram of an embodiment of a process for forming a silicon layer in accordance with the present invention. Each of the blocks represents a chamber into which the substrate is transferred using a form of conveyor belt from the preceding chamber. Each chamber is interconnected with the adjacent chamber through an interlock (not needed to be hermetic seal) and kept under positive N₂ pressure in order to maintain O₂ levels at sub 10 ppm in the atmosphere. The O₂ environment is needed to protect the films from contamination and adverse changes in the film properties.

In this particular embodiment, the substrate comprises glass having a thickness of 2-3 mm. Equipment used in the manufacture of flat panel display devices could be applicable to form the silicon layers of the present invention. For example, the tools used in the fabrication of flat panel displays for generation 4 (Glass—730 mm×920 mm) could be used.

It is understood that the substrate has its bottom side coated with a material that protects the surface from damage in processing, but which can later be removed. The top side of the substrate may be coated with an intermediate layer or an active layer—serving as an overlying film.

Chambers 2 through 14 are maintained under positive N₂ pressure in order to avoid the presence of O₂ contaminant for most of the subsequent processes. One of the goals of the inline processing approach is to keep the needed process time in each chamber roughly the same as the others. For this reason, some process steps expected to take longer than the others are broken into 2 or more steps.

1. Prime/Dry

The substrate is loaded into the chamber. A priming process is applied which prepares the top surface so the Aluminum film will adhere. Procedures used in practicing this step include exposing the substrate to UV radiation in the presence of an oxidizing environment such as O₂ or a halogen gas.

2. N₂ Purge [O₂<10 ppm]

The substrate is transferred into this chamber using a conveyor belt. The chamber can be sealed but does not need to be hermitic. It is kept small so that it can be easily and quickly purged with N₂ gas in order to remove O₂. An O₂ meter can be used to determine when the substrate is ready for transfer.

3. Ink Jet Print Aluminum Barriers

In this example, the barrier structures are deposited using an ink jet printer type process, with the lines delineated by writing. The ink jet heads would be mounted onto X-Y translation apparatus. Thicknesses of the barriers should be relatively uniform, so dispensing rates and traversal rates should remain constant.

Alternative embodiments could include screen printing, or film deposition/photoresist application/mask exposure/development/etch and strip.

Other alternative embodiments could involve the application of a thin insulating film, with laser etching through the insulating film to form the pattern for barrier structures. Electroplating with Aluminum or some other conductive material could form the barriers, followed by removal of the insulating material.

Still other alternative embodiments could involve the application of a thin insulating film (e.g. SiO₂). The inverse of the barrier pattern could be screen printed using HF resistant material such as PMMA, and then the insulating material could be etched and the PMMA removed, followed by electroplating.

Materials other than Al could be used in this process. Alternative conductive materials might include Silver, Titanium, Zinc, etc. Non conductive materials might include SiO₂, deposited as a siloxizane or polymeric materials such as PMMA.

4. Bake Remove Solvent

This step is applicable where the barriers are formed utilizing an ink jet process. Specifically, most inks are dispersed in a solvent, which must subsequently be removed through a heat treatment.

5. Anodize/Rinse/Dry

In this step, a voltage is applied to the Al barriers in an acidic solution to form a hard, Al₂O₃ insulating surface on Al barriers with nucleation sites. This step is performed with the understanding that electrical contacts to conductive (i.e. doped) silicon or a metal film overlying the substrate is desired, with insulation from the silicon film being deposited using the liquid silane.

6. Prime/Dry

This step entails a treatment of the surfaces of both the anodized aluminum and the underlying film so as to enhance adhesion and wettability of the liquid silane to be applied. Techniques for this include UV exposure in an oxidizing atmosphere, light electrical discharge in an oxidizing atmosphere, and rise with an organic compound rinse.

7. Cool Substrate˜Melting Point

In this step, the substrate is cooled. This may be done by either placing the substrate on a cooled plate at a temperature near to (but above) the liquid silane melting point (e.g. 16.5° C. for CHS or −10.5° C. for CPS), or blowing the substrate with cooled N₂.

8. Immerse in Liquid Silane, Freeze

In this step, the substrate is horizontally lowered into a pan of liquid silane kept at a temperature slightly above its melting point. As the substrate is lifted out of pool, the excess Liquid is naturally drained off the sides leaving the pool of liquid silane at approximately a depth equivalent to the height of the Al barrier structures (nominally >10 μm or so).

Then, a plate cooled to a temperature below the melting point of the liquid silane is raised below the substrate, until it comes in physical contact with the substrate. The liquid silane on the substrate then cools to its freezing point.

9. Scan—IR & UV Lamp

The substrate then enters the N₂ purged chamber and is clamped to a plate cooled to below the melting point of the liquid silane. A series of alternating linear IR and UV lamps scan the surface of the substrate. The focused IR lamp irradiates and melts a line of the frozen liquid silane running across the width of the substrate. This is followed by a linear UV lamp inducing polymerization of the melt. After the UV Lamp is another IR Lamp which further melts the frozen liquid silane. This alternating assembly scans [and, if necessary, re-scans] the substrate surface until the liquid silane has been fully polymerized.

10. Scan—IR & UV Lamp

This chamber performs the same function as the previous chamber. It is needed only if the polymerization is incomplete after the first chamber.

11. Anneal—Heat&IR

The substrate is placed on a plate which is heated to a temperature ranging from about 350-750° C. An IR Lamp, similar to the one used to melt the frozen liquid silane, scans the surface of the substrate to heat the polymerized Silane to annealing temperatures. If necessary, H₂ is mixed with the N₂ ambient in order to passivate the grain boundary charge traps.

12. Anneal—Heat & IR

This chamber performs the same basic function as the previous chamber, but permits the substrate to undergo a two step thermal treatment without having to potentially slow down the Inline Processing.

3. Cool to Ambient

In this chamber the substrate is slowly cooled back down to room temperature ambient using a cooled plate on which the substrate rests. If necessary, a second chamber may be needed for this purpose.

### Example 2

FIG. 7 provides an illustration of another example of a process flow illustrating an embodiment of the present invention which implements formation of a silicon film in a manner that optimizes the flow in a production manufacturing environment. Two advantages are offered by this approach. First, it does not require the ink printing of the barrier material. Secondly, it uses electroplating to obtain self aligned barriers. In addition, the Poly Methyl Methacrylate (PMMA) can be replaced by a positively photoresist that might offer the additional advantage of increasing the process time by simply exposing the barrier features using a scanned laser beam. It should be possible to use this approach to create high aspect ratio (i.e. vertical) profile of the barriers.

1. Prime/Dry

Again, the substrate is loaded into the chamber. A priming process is applied which prepares the top surface so the PMMA will adhere. Examples of such a priming process include but are not limited to exposing the substrate to UV radiation in the presence of an oxidizing environment such as O₂ or a halogen gas. Application of an organic liquid primer is another possible approach.

2. Coat PMMA

In this chamber the PMMA is applied using a curtain coater nozzle.

3. Laser Etch Pattern in PMMA

In this step, a laser(s) is scanned across the substrate with a pattern replicating the desired pattern of the barrier structure. The laser removes the PMMA in the desired areas.

In another embodiment, the substrate may be coated with a positively developed photoresist. The laser scans the same pattern and then the substrate is placed in a developer. The exposed areas dissolve in the developer leaving deep cavities exposing the underlying film, which is understood to be conductive.

4. Electroplate Aluminum

The substrate bearing exposed areas defining desired locations for the Al barriers, is then immersed in an Al electroplating solution, and a voltage is applied to the area of the underlying film.

5. Strip PMMA/Rinse/Dry

In this step, the PMMA is removed in acid, and the substrate is rinsed and dried.

6. Anodize/Rinse/Dry

Next, a voltage is applied to the Al barriers in acidic solution to form the hard Al₂O₃ insulating surface on the Al barriers with nucleation sites. It is understood that electrical contacts to conductive silicon or a metal underlying film is desired, while electrical contact with the film deposited with the liquid silane is avoided.

7. Prime/Dry

Next, the barriers and the underlying film are primed and dried. This entails a treatment of the surfaces of both the anodized aluminum and the underlying film so as to enhance the adhesion and wettability of the liquid silane that is to be applied. Possible priming techniques include UV exposure in an oxidizing atmosphere, light electrical discharge in an oxidizing atmosphere, or rinsing with an organic compound rinse.

8. N₂ Purge [O₂<10 ppm]

The substrate then enters a chamber where it is immersed in an O₂ free atmosphere.

9. Cool Substrate˜Melting Point

Next, the substrate is cooled at a temperature near (but above), the melting point of the liquid silane (16.5° C. for CHS or −10.5° C. for CPS). This may be accomplished by placing a cooling plate into contact with the substrate, or by exposing the substrate to cooled N₂.

The remainder of the processing follows along the lines of FIG. 6.

While the above embodiments describe formation of a silicon film utilizing a substrate bearing barrier structure, the present invention is not limited to this approach. Alternative embodiments could forgo the use of barriers and still remain within the scope of the present invention.

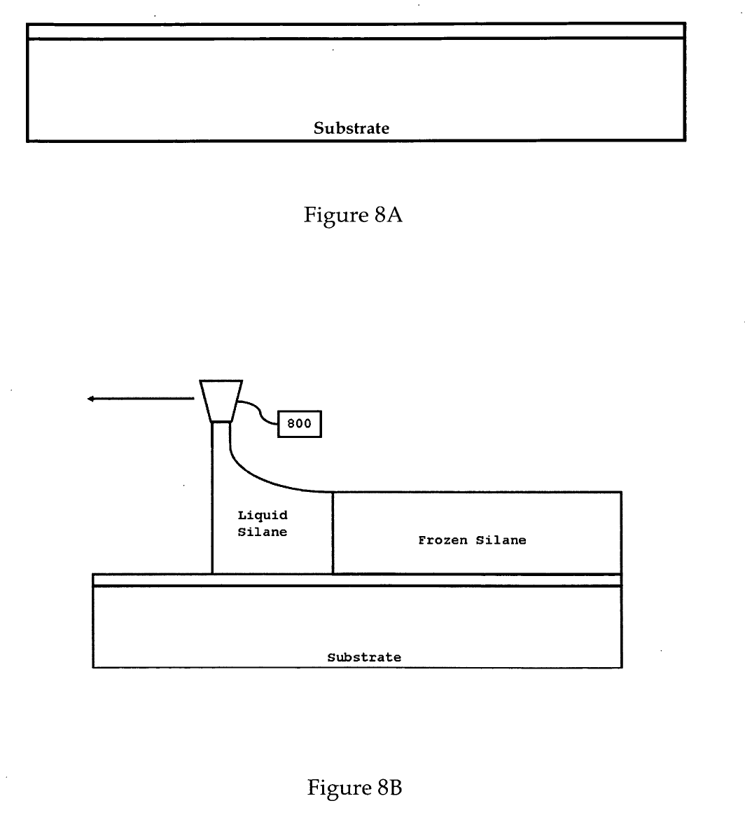

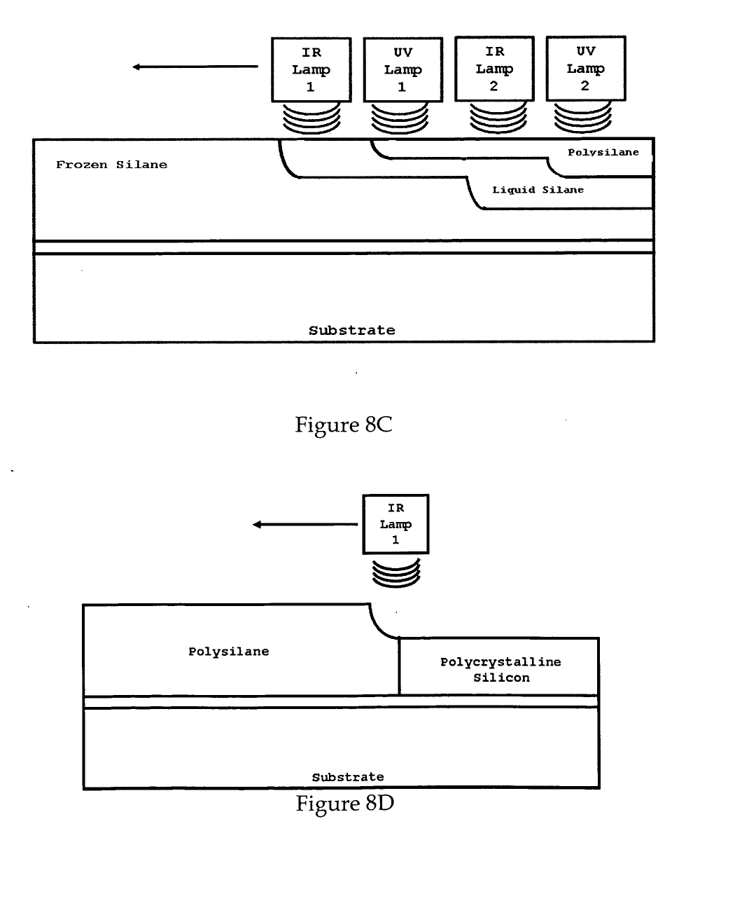

For example, FIGS. 8A-D show simplified cross-sectional views of a barrier-less embodiment of a method for forming a silicon film in accordance with the present invention. In a first step shown in FIG. 8A, a treated substrate is provided.

In a second step, the liquid silane is applied to the treated substrate. The thickness of the applied film is controlled only by the dispense rate, rate of cooling, and linear scan rate of dispenser or substrate.

FIG. 8B graphically shows how one implementation of this approach might work. A curtain coating dispenser head 800 traverses across the substrate in a linear motion. The width of the head is at or near the width of the substrate so that as it moves the liquid near the melting point of the liquid silane is dispensed. Within a matter of milliseconds the liquid freezes into frozen silane. As it solidifies the film reduces in thickness since the density of the solid silane is higher than the liquid.

The thickness of the coating is determined by the dispense rate at the coating head and the rate at which the head scans across the substrate surface. The rate of cooling of the substrate must be quick enough to prevent much of the liquid polysilane from dispersing off the substrate.

In other embodiments, it is possible to keep the coating head fixed but move the substrate linearly across the coating head. It is also possible to dispense the liquid using ink jet head(s). Use of a dense linear array of heads would have the same effect as the box coating head. It is also possible to use this technique write frozen silane patterns on a substrate.

FIG. 8C shows polymerization of the frozen liquid silane. An infrared lamp (or series of lamps in a linear array) forms a heat beam running across the width of the substrate. As the infrared beam scans across the substrate the liquid silane melts along the beam width. This heat beam exposure is followed shortly by exposure to a linear UV lamp beam polymerizing the liquid silane monomer. It is necessary to melt the silane to a liquid so that the silane is mobile enough that once it is exposed to UV radiation it can form a chemical bond with a Si atom from a nearby silane. Without the mobility in the melt, it is difficult for polymerization to take place. The substrate is kept at a temperature below the melting point of the liquid silane.

The scan rate of the lamps, their radiance, the choice of wavelength, and the substrate temperature, along with the melting point of the liquid silane, influence how fast the polymeric material can form using this approach. As shown in the drawing, multiple IR and UV lamp arrays may be needed to fully cause the polymerization of the materials, as a single exposure to a UV lamp may not be sufficient.

Depending upon the particular embodiment, the lamps can be physically scanned across the length of the substrate, and/or the substrate can move across fixed lamp assemblies. If the substrate and the underlying film are transparent to either IR and/or UV radiation, the appropriate lamp could be placed beneath the substrate to aid in the melting and/or polymerization process. The lamps can be either conventional lamps with appropriate cylindrical lenses, LED arrays (with multiple arrays staggered in parallel), laser diode arrays or any light source that can be formed into a linear beam.

In a next step of the process, as shown in FIG. 8D, the silane material is annealed. According to one embodiment, a temperature of the substrate is increased to drive off much of the H₂ and residual silanes. This annealing will produce a high quality silicon film, maximizing carrier lifetimes and minimizing impurities and creating a stable film.

The specific type of silicon film that is formed (e.g. amorphous, nanocrystalline, or polycrystalline) depends on the particular conditions of the annealing. Specifically, the anneal temperature, ambient atmosphere, and presence of nucleation sites on the substrate surface can influence the type of silicon film that is formed.

FIG. 8D shows use of an Infrared Arc Lamp beam running the length of the substrate width in order to anneal the Polysilane. The intensity of the IR lamp, its focal point at the substrate surface, its scan rate, the spectral absorption of the film and the initial temperature of the substrate collectively control the local temperature of the annealed film.

### Example 3

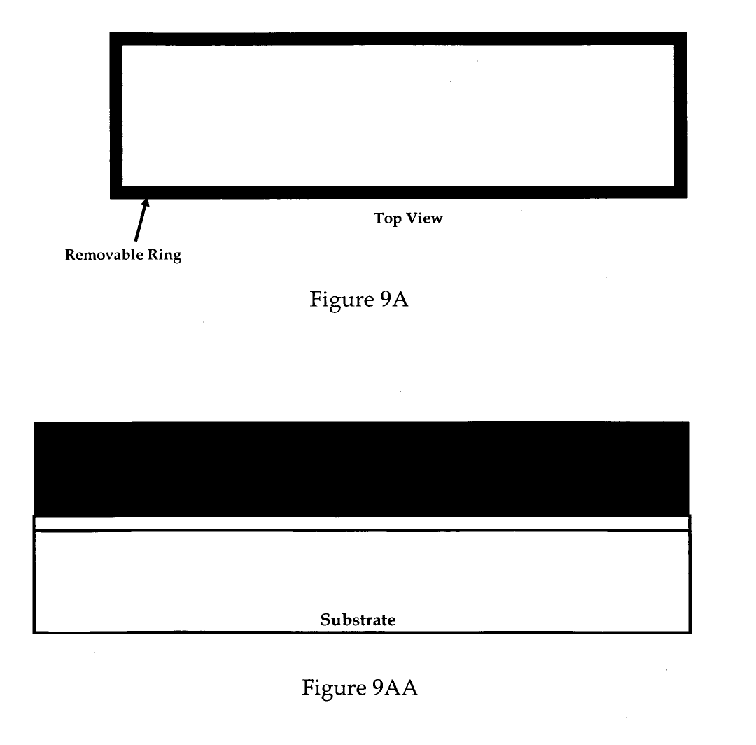

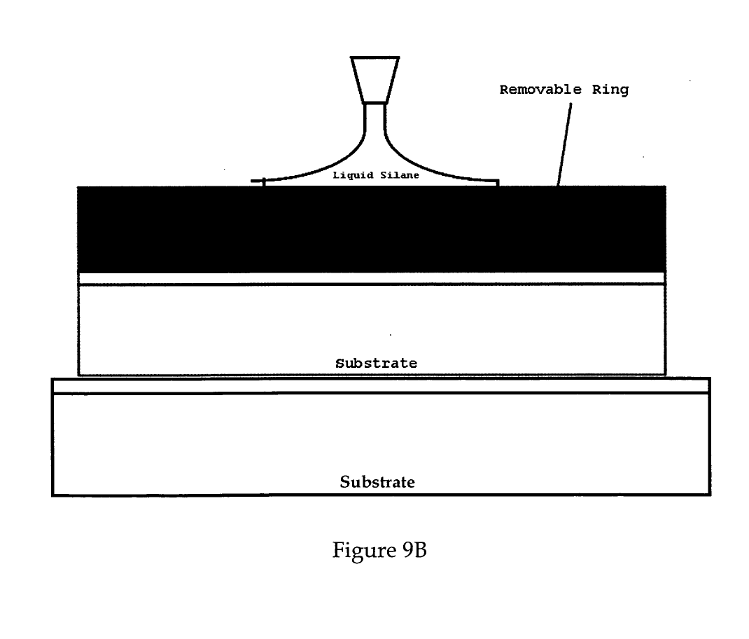

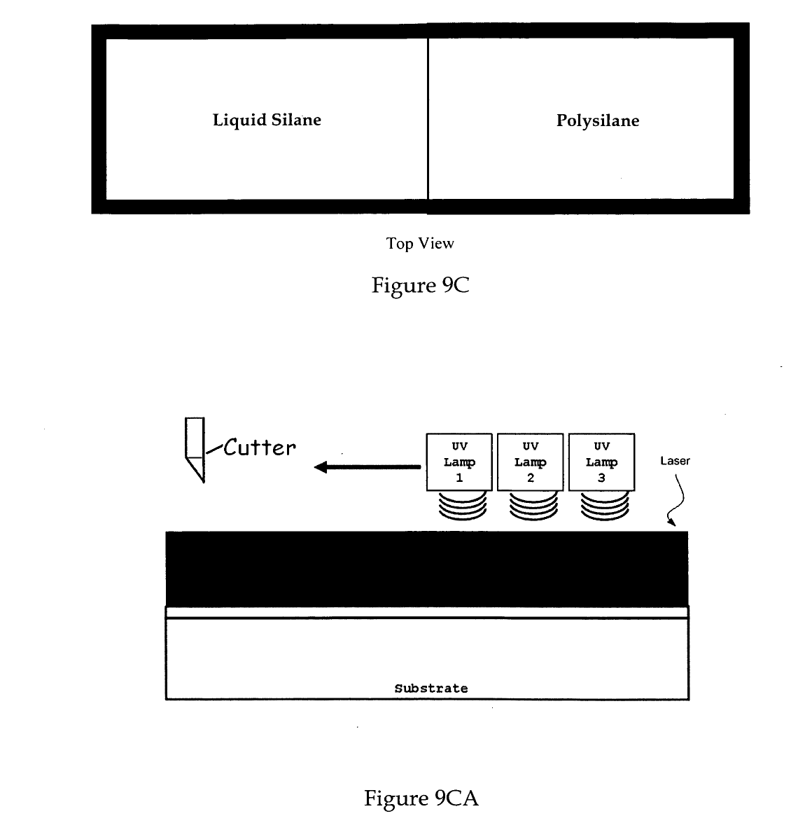

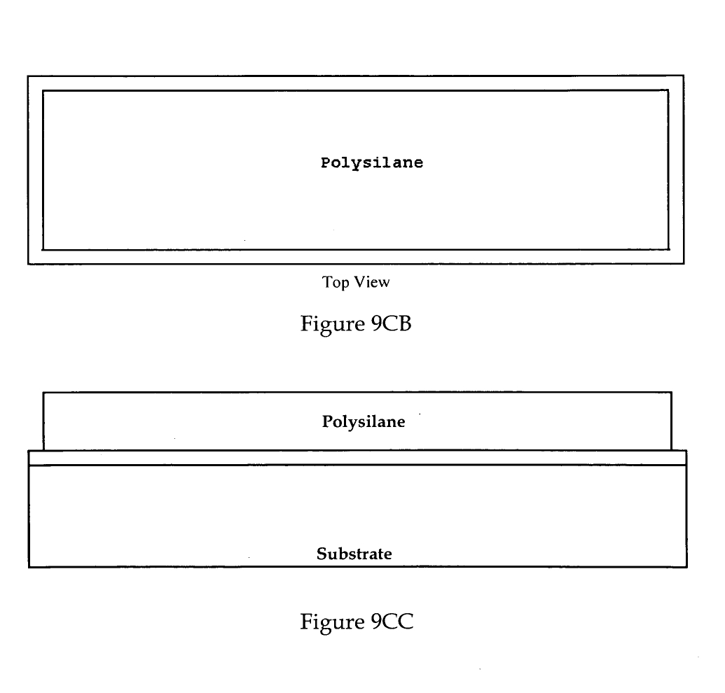

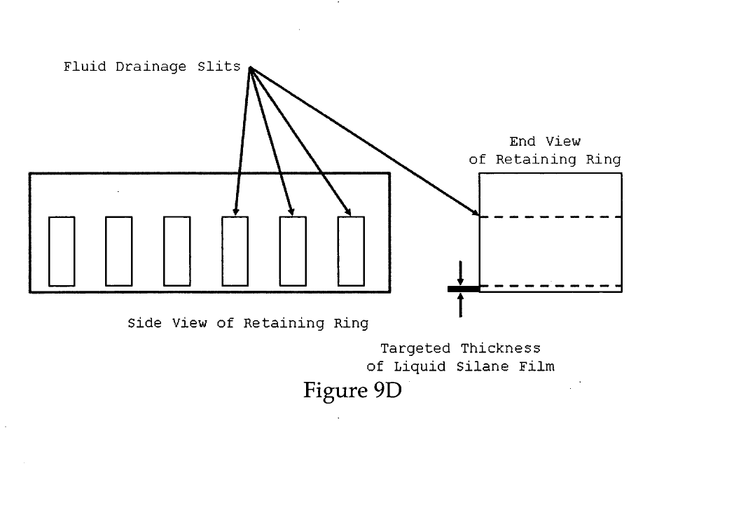

FIGS. 9A-9C show another method for creating a barrier which can retain the liquid silane fluid during the coating process.

FIG. 9A shows a top view, and FIG. 9AA shows a side view, depicting how a removable retaining ring can be press fitted against the perimeter of the substrate. If, for example, the substrate is a glass sheet 1.5×1.0 square meters the retaining ring would typically match the outer perimeter in dimensions but have a width approximating 1 centimeter.

After the retaining ring is pressed against the substrate the liquid silane is dispensed into the ring as shown in FIG. 9B. The liquid fills the cavity formed by the walls of the retaining ring.

Once the liquid has been dispensed, UV lamps scan the surface of the coated substrate to induce polymerization of the liquid silane into polysilane solid, as shown in the top and side views of FIGS. 9C-9CA. Once the liquid silane has been converted into the solid polysilane, the retaining ring can be removed without having the liquid drain away.

If necessary, the retaining ring can employ a flexible gasket material between it and the substrate, in order to ensure a tight seal. Also, to ensure that no lifting of the polysilane takes place when the retaining ring is removed, a laser could be used to ablate the material at the edge near the retaining ring. An alternative approach to ensuring no lifting of the polysilane with removal of the ring, is to use a knife edge cutter to sever the polysilane film at the inner edge of the retaining ring.

Following removal of the ring, as shown in FIGS. 9CB and 9CC, the polysilane film can be processed to form a crystalline, polycrystalline or amorphous silicon film as described in EXAMPLES 1 or 2 above.

Besides defining the perimeter of the coated polysilane film, the retaining ring may also provide a way for excess fluid to drain away from the substrate, and provide a mechanism for controlling the thickness of the liquid silane coating. FIG. 9D shows an example design for such a retaining ring. A small lip protrudes inwards from the main retaining wall perimeter with a height matching the targeted liquid silane film thickness. If, for example, the target liquid silane film thickness is 10 μm, then this lip could be 10 μm high. Any fluid dispensed exceeding this thickness will then drain away from the substrate through the drainage slits, into a pan beneath the substrate that is used to collect the excess fluid. This excess fluid can then be filtered and re-used for another substrate coating.

### Example 4

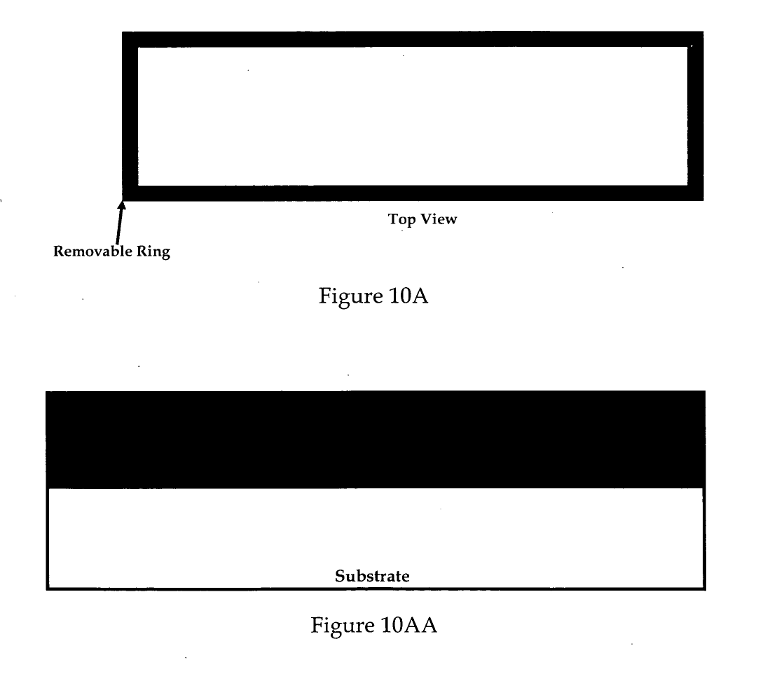

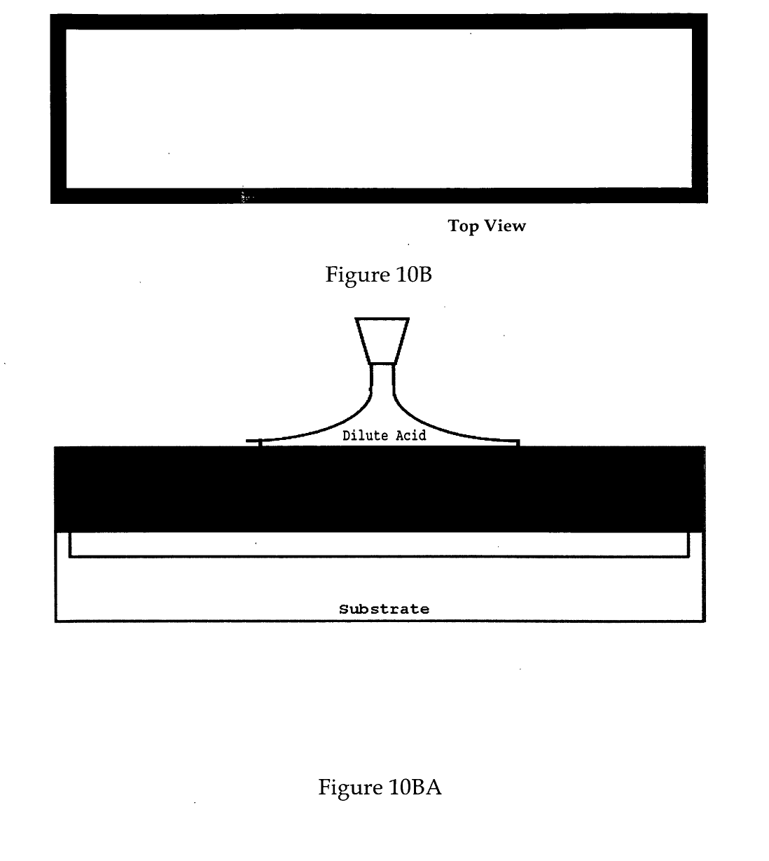

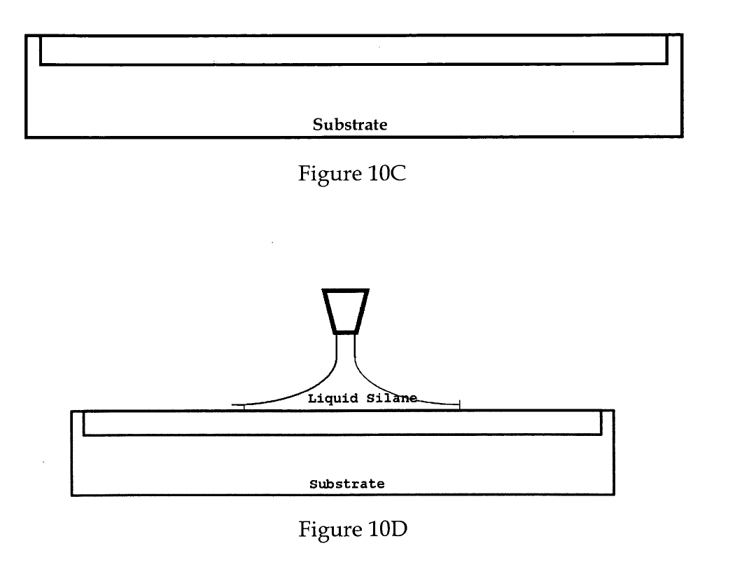

FIGS. 10A-10D show another method for creating a barrier which can retain the liquid silane fluid during the coating process.

As shown in the top and side views of FIGS. 10A-10AA respectively, a retaining ring like that described in Example 3 is placed over the substrate. In alternative embodiments of this invention a retaining ring could be patterned over the substrate using a polyimide or other thick polymeric material which could be easily removed later using an acid or developer. This type of ring could be patterned using a screen printer, ink jet printer or lithographic exposure/development equipment.

With the retaining ring in place, a dilute acid or other material which can etch the substrate material is dispensed as shown in the top and side views of FIGS. 10B-10BA. This material removes material from the surface of the substrate creating a cavity in the substrate. The outer dimensions of the cavity are determined by the size of the retaining ring. The depth of the cavity is fixed by the rate at which the acid removes the substrate material, and the dwell time of the acid in the retaining ring. The retaining ring is created using a material impervious to the acid.

After the appropriate dwell time the substrate and retaining ring are rinsed in water thoroughly to remove all the residual etching material. After the rinsed retaining ring is removed as shown in FIG. 10C leaving a cavity inside the substrate. If a polyimide or other polymeric material is used to form the retaining wall, it would need to be removed in an etching fluid which dissolves the wall but does not affect the substrate, such as sulphuric acid.

Then, as shown in FIG. 10D the liquid silane is dispensed and the proper thickness forms in the cavity etched as described in FIGS. 10A-10C. Excess liquid silane spills over the sides of the substrate and is collected in a pan beneath the substrate. This collected material can then be filtered and re-used.

Then, for example, the polysilane film can be processed to form a crystalline, polycrystalline or amorphous silicon film as described in EXAMPLES 1 or 2 above.

As previously emphasized, methods or processes in accordance with embodiments of the present invention for applying liquid silane, can employ coating equipment already used in the printing industry to deliver other types of materials. Examples of existing equipment which may be utilized to deliver liquid silane, includes but is not limited to, a box coater, a roller coater, a curtain coater, a spray coater, a gravure coater, a roto-gravure coater, or a screen printer.

While the above is a full description of certain specific embodiments, various modifications, alternative constructions and equivalents may be used. Therefore, the above description and illustrations should not be taken as limiting the scope of the present invention which is defined by the appended claims.

What is claimed is:

1. A process for forming a silicon film, the process comprising:
providing a substrate;
cooling the substrate to below a temperature;
applying a cyclosilane material in a liquid state to the cooled substrate, such that the liquid cyclosilane material is converted into a solid state;
melting the solid cyclosilane material; and
causing polymerization of the melted cyclosilane material to form the crystalline silicon film having a thickness.

2. The process of claim 1 wherein the thickness is greater than 1 μm.

3. The process of claim 1 wherein the polymerization produces a crystalline silicon film.

4. The process of claim 3 wherein the crystalline silicon film comprises polysilicon.

5. The process of claim 1 wherein the polymerization produces an amorphous silicon film.

6. The process of claim 1 wherein the thickness is less than 1 μm, the process further comprising repeating the application of cyclosilane material to the crystalline silicon film, melting the solid cyclosilane material, and causing polymerization of the melted cyclosilane material, such that a total thickness of the crystalline silicon film is greater than 1 μm.

7. The process of claim 1 further comprising controlling at least one process parameter selected from a rate of application of the liquid and the temperature, in order to determine the thickness.

8. The process of claim 1 wherein the liquid cyclosilane is selected from cyclopentasilane or a derivative thereof, or cyclohexasilane or a derivative thereof.

9. The process of claim 8 wherein the liquid cyclosilane further comprises a mixture of cyclopentasilane and a derivative of cyclopentasilane bearing a boron- or phosphorus-containing substituent.

10. The process of claim 1 wherein the substrate is provided with a raised barrier structure enclosing a reservoir region for retaining the liquid cyclosilane.

11. The process of claim 10 wherein the raised barrier structure is formed by electroplating.

12. The process of claim 10 further comprising forming an oxide on the raised barrier structure.

13. The process of claim 12 wherein the oxide is formed by anodization.

14. The process of claim 10 further comprising imparting a texture to the raised barrier structure to offer a nucleation site to the crystalline silicon.

15. The process of claim 1 performed in a series of in-line processing chambers.

16. A process for forming a crystalline silicon film, the process comprising:
providing a substrate having a raised barrier with a height enclosing a reservoir region;
applying a liquid cyclosilane material to the reservoir region; and
causing polymerization of the cyclosilane material to form the crystalline silicon film having a thickness equal to or less than the height.

17. The process of claim 16 wherein the thickness is greater than 1 μm.

18. The process of claim 16 wherein the polymerization produces a crystalline silicon film.

19. The process of claim 18 wherein the crystalline silicon film comprises polysilicon.

20. The process of claim 16 wherein the polymerization produces an amorphous silicon film.

21. The process of claim 16 wherein the thickness is less than 1 μm, the process further comprising repeating the application of cyclosilane material to the crystalline silicon film, and causing polymerization of the cyclosilane material, such that a total thickness of the crystalline silicon film is greater than 1 μm.

22. The process of claim 16 further comprising controlling at least one process parameter selected from a rate of application of the liquid and a viscosity of the liquid, in order to determine the thickness.

23. The process of claim 16 wherein the liquid cyclosilane is selected from cyclopentasilane or a derivative thereof, or cyclohexasilane or a derivative thereof.

24. The process of claim 23 wherein the liquid cyclosilane further comprises a mixture of cyclopentasilane and a derivative of cyclopentasilane bearing a boron- or phosphorus-containing substituent.

25. The process of claim 16 wherein the liquid cyclosilane is applied by immersing the substrate within a bath of the liquid cyclosilane.

26. The process of claim 16 wherein the substrate is provided with an overlying doped silicon layer, and the barriers are self-aligned and provide a metallized contact to the doped silicon layer.

27. The process of claim 16 wherein the raised barrier structure is formed by electroplating.

28. The process of claim 16 further comprising forming an oxide on the raised barrier structure.

29. The process of claim 28 wherein the oxide is formed by anodization.

30. The process of claim 16 further comprising imparting a texture to the raised barrier structure to offer a nucleation site to the crystalline silicon.

31. The process of claim 16 performed in a series of in-line processing chambers.

32. An apparatus comprising a substrate bearing a polycrystalline silicon layer having a height greater than 0.1 μm and circumscribed by a raised barrier structure.

33. The apparatus of claim 32 wherein the raised barrier structure comprises a metal.

34. The apparatus of claim 32 wherein the raised barrier structure bears an oxide layer.

35. The apparatus of claim 34 wherein the oxide layer is an anodized layer.

36. The apparatus of claim 32 wherein the polycrystalline silicon layer comprises polysilicon.

37. The apparatus of claim 36 wherein the polycrystalline silicon layer exhibits a grain size of about 1 μm

38. The apparatus of claim 32 wherein the silicon layer comprises amorphous silicon

39. The apparatus of claim 32 wherein the raised barrier structure includes a texture for serving as a nucleation site for formation of grains of polysilicon.

40. The process of claim 1 wherein the cyclosilane material is applied by a device employed for another purpose in the printing industry, the device selected from a box coater, a roller coater, a curtain coater, a spray coater, a gravure coater, a roto-gravure coater, or a screen printer.

41. The process of claim 16 wherein the liquid cyclosilane material is applied by a device employed for another purpose in the printing industry, the device selected from a box coater, a roller coater, a curtain coater, a spray coater, a gravure coater, a roto-gravure coater, or a screen printer.

42. A process for forming a crystalline silicon film, the process comprising:
attaching to a surface of a substrate, a retaining ring having a height;
applying a liquid cyclosilane material to a region within the retaining ring; and
causing polymerization of the cyclosilane material to form the crystalline silicon film within the ring and having a thickness equal to or less than the height.

43. The process of claim 42 wherein the thickness is greater than 1 μm.

44. The process of claim 42 wherein the polymerization produces a crystalline silicon film.

45. The process of claim 44 wherein the crystalline silicon film comprises polysilicon.

46. The process of claim 42 wherein the polymerization produces an amorphous silicon film.

47. The process of claim 42 wherein the thickness is less than 1 μm, the process further comprising:
repeating application of cyclosilane material to the crystalline silicon film, melting the solid cyclosilane material, and causing polymerization of the melted cyclosilane material, such that a total thickness of the crystalline silicon film is greater than 1 μm.

48. The process of claim 42 wherein the liquid cyclosilane is selected from cyclopentasilane or a derivative thereof, or cyclohexasilane or a derivative thereof.

49. The process of claim 47 wherein the liquid cyclosilane further comprises a mixture of cyclopentasilane and a derivative of cyclopentasilane bearing a boron- or phosphorus-containing substituent.

50. The process of claim 42 performed in a series of in-line processing chambers.

51. The process of claim 42 further comprising applying a laser to ablate the crystalline silicon film proximate to the retaining to allow removal of the retaining ring.

52. The process of claim 42 wherein the liquid cyclosilane material is applied by a device employed for another purpose in the printing industry, the device selected from a box coater, a roller coater, a curtain coater, a spray coater, a gravure coater, a roto-gravure coater, or a screen printer.

53. A process for forming a crystalline silicon film, the process comprising:
etching into a substrate, a cavity having a depth;
applying a liquid cyclosilane material to the cavity; and
causing polymerization of the cyclosilane material to form a crystalline silicon film having a thickness equal to or less than the depth.

54. The process of claim 53 wherein the thickness is greater than 1 μm.

55. The process of claim 53 wherein the polymerization produces a crystalline silicon film.

56. The process of claim 55 wherein the crystalline silicon film comprises polysilicon.

57. The process of claim 53 wherein the polymerization produces an amorphous silicon film.

58. The process of claim 53 wherein the thickness is less than 1 μm, the process further comprising:
repeating application of cyclosilane material to the crystalline silicon film, melting the solid cyclosilane material, and causing polymerization of the melted cyclosilane material, such that a total thickness of the crystalline silicon film is greater than 1 μm.

59. The process of claim 53 wherein the liquid cyclosilane is selected from cyclopentasilane or a derivative thereof, or cyclohexasilane or a derivative thereof.

60. The process of claim 59 wherein the liquid cyclosilane further comprises a mixture of cyclopentasilane and a derivative of cyclopentasilane bearing a boron- or phosphorus-containing substituent.

61. The process of claim 53 performed in a series of in-line processing chambers.

62. The process of claim 53 wherein the liquid cyclosilane material is applied by a device employed for another purpose in the printing industry, the device selected from a box coater, a roller coater, a curtain coater, a spray coater, a gravure coater a roto-gravure coater, or a screen printer.
